(19) United States
(12) Patent Application Publication
(10) Pub. No.: US 2020/0273716 A1
(43) Pub. Date: Aug. 27, 2020

(54) SEMICONDUCTOR DEVICE AND METHOD FOR MANUFACTURING SEMICONDUCTOR DEVICE

(71) Applicant: Mitsubishi Electric Corporation, Chiyoda-ku (JP)

(72) Inventors: Yuji SATO, Chiyoda-ku (JP); Tsuyoshi URAJI, Chiyoda-ku (JP); Jun FUJITA, Chiyoda-ku (JP); Motoru YOSHIDA, Chiyoda-ku (JP)

(73) Assignee: Mitsubishi Electric Corporation, Chiyoda-ku (JP)

(21) Appl. No.: 16/620,183

(22) PCT Filed: Apr. 12, 2018
(86) PCT No.: PCT/JP2018/015333

§ 371 Date: Dec. 6, 2019

(30) Foreign Application Priority Data
Jul. 7, 2017 (JP) 2017-133686

(51) Int. Cl. H01L 21/3205; H01L 23/532; H01L 21/768; H01L 23/00

(52) U.S. Cl. CPC H01L 21/32051; H01L 23/53209; H01L 2224/4847; H01L 24/73; H01L 2224/45147; H01L 21/76838

(57) ABSTRACT

A semiconductor device is provided that can minimize the occurrence of poor joining between a copper electrode and a copper wire. The semiconductor device includes a semiconductor substrate; a copper electrode layer formed on the semiconductor substrate; a metallic thin-film layer formed on the copper electrode layer for preventing oxidation of the copper electrode layer, the metallic thin-film layer having an opening through which the copper electrode layer is exposed, the opening being located on an inner side relative to an outer periphery of the metallic thin-film layer; and an interconnection member containing copper as a main component, the interconnection member including a joining region covering the opening, the interconnection member being joined to the metallic thin-film layer and joined to the copper electrode layer in the opening.

### TECHNICAL FIELD

The present invention relates to a semiconductor device using a copper electrode, and a method for manufacturing a semiconductor device using a copper electrode.

### BACKGROUND ART

As a conventional semiconductor device, a semiconductor device is disclosed in which a copper bump is provided on a semiconductor element, with a copper wire connected to the copper bump. Also, a semiconductor device is disclosed in which an oxidation resistant coating is formed on a copper bump for preventing oxidation of the copper bump (e.g., PTL 1).

### CITATION LIST

### Patent Literature

PTL 1: Japanese Patent Laying-Open No. 2014-22692 (page 6, FIG. 3)

### SUMMARY OF INVENTION

### Technical Problem

However, in the conventional semiconductor device, when a copper wire is joined to a copper bump, an oxidation resistant coating may be removed from the copper bump at the region outside of the joining region between the copper bump and the copper wire. If the oxidation resistant coating is removed at the region outside of the joining region, the exposed copper bump surface may be oxidized, thus causing poor joining between the copper bump and the copper wire.

An object of the present invention, which has been made to solve such a problem, is to provide a semiconductor device that minimizes the occurrence of poor joining at a joining portion between a copper electrode and a copper wire.

### Solution to Problem

A semiconductor device according to the present invention includes: a semiconductor substrate; a copper electrode layer formed on the semiconductor substrate; a metallic thin-film layer formed on the copper electrode layer for preventing oxidation of the copper electrode layer, the metallic thin-film layer having an opening through which the copper electrode layer is exposed, the opening being located on an inner side relative to an outer periphery of the metallic thin-film layer; and an interconnection member containing copper as a main component, the interconnection member including a joining region covering the opening, the interconnection member being joined to the metallic thin-film layer and joined to the copper electrode layer in the opening.

### Advantageous Effects of Invention

The present invention includes an interconnection member including a joining region which is joined to a copper electrode layer and a metallic thin-film layer. Thus, the copper electrode layer and the interconnection member can be joined together, with minimized occurrence of poor joining.

### BRIEF DESCRIPTION OF DRAWINGS

FIG. 1 is a schematic plan view showing a semiconductor device in embodiment 1 of the present invention.

FIG. 2 is a schematic cross-sectional view showing a semiconductor device in embodiment 1 of the present invention.

FIG. 3 is a schematic cross-sectional view showing a step for manufacturing a semiconductor device in embodiment 1 of the present invention.

FIG. 4 is a schematic cross-sectional view showing a step for manufacturing a semiconductor device in embodiment 1 of the present invention.

FIG. 5 is a schematic cross-sectional view showing a step for manufacturing a semiconductor device in embodiment 1 of the present invention.

FIG. 6 is a schematic cross-sectional view showing a step for manufacturing a semiconductor device in embodiment 1 of the present invention.

FIG. 7 is a schematic cross-sectional view showing a step for manufacturing a semiconductor device in embodiment 1 of the present invention.

FIG. 8 is a schematic cross-sectional view showing a step for manufacturing a semiconductor device in embodiment 1 of the present invention.

FIG. 9 is a schematic cross-sectional view showing a step for manufacturing a semiconductor device in embodiment 1 of the present invention.

FIG. 10 is a schematic plan view showing a semiconductor device in embodiment 2 of the present invention.

FIG. 11 is a schematic cross-sectional view showing a semiconductor device in embodiment 2 of the present invention.

FIG. 12 is a schematic cross-sectional view showing a step for manufacturing a semiconductor device in embodiment 2 of the present invention.

FIG. 13 is a schematic cross-sectional view showing a step for manufacturing a semiconductor device in embodiment 2 of the present invention.

FIG. 14 is a schematic cross-sectional view showing a step for manufacturing a semiconductor device in embodiment 2 of the present invention.

FIG. 15 is a schematic cross-sectional view showing a step for manufacturing a semiconductor device in embodiment 2 of the present invention.

FIG. 16 is a schematic cross-sectional view showing a step for manufacturing a semiconductor device in embodiment 2 of the present invention.

FIG. 17 is a schematic cross-sectional view showing a step for manufacturing a semiconductor device in embodiment 2 of the present invention.

FIG. 18 is a schematic cross-sectional view showing a step for manufacturing a semiconductor device in embodiment 2 of the present invention.

FIG. 19 is a schematic cross-sectional view showing a step for manufacturing a semiconductor device in embodiment 2 of the present invention.

FIG. 20 is a schematic cross-sectional view showing a step for manufacturing a semiconductor device in embodiment 2 of the present invention.

FIG. 21 is a schematic cross-sectional view showing a step for manufacturing a semiconductor device in embodiment 2 of the present invention.

FIG. 22 is a schematic cross-sectional view of another jig to be used for a step for manufacturing a semiconductor device in embodiment 2 of the present invention.

FIG. 23 is a schematic cross-sectional view of another jig to be used for a step for manufacturing a semiconductor device in embodiment 2 of the present invention.

### DESCRIPTION OF EMBODIMENTS

First, a general configuration of a semiconductor device of the present invention is described with reference to the drawings. The drawings are schematic representations and do not reflect the exact measurements (e.g., size) of the components shown. The components denoted by identical reference signs are identical or corresponding components, which is common to the whole description.

### Embodiment 1

First, a configuration of a semiconductor device 100 in embodiment 1 of the present invention is described.

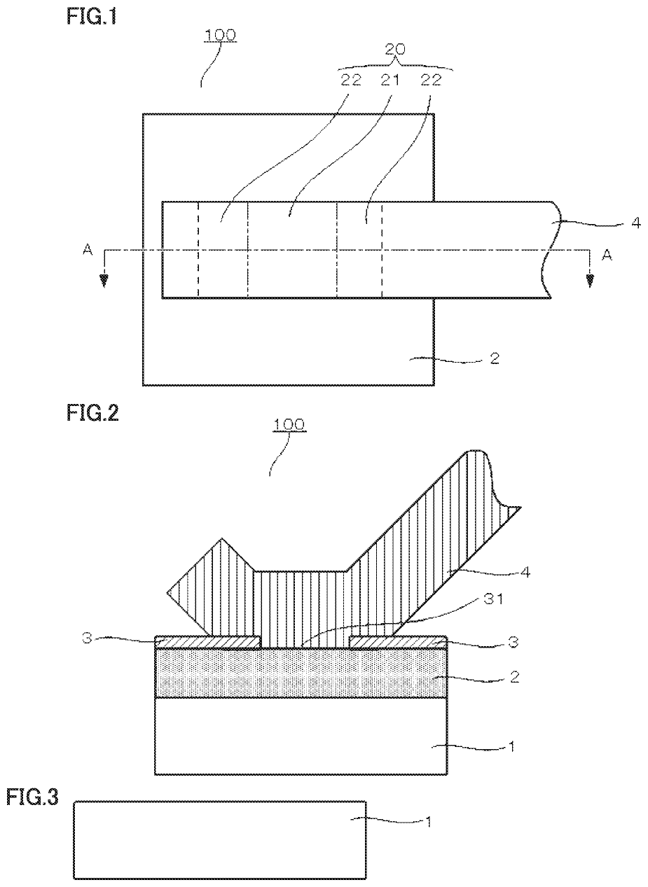

FIG. 1 is a schematic plan view showing a semiconductor device in embodiment 1 of the present invention. FIG. 2 is a schematic cross-sectional view showing a semiconductor device in embodiment 1 of the present invention. FIG. 2 is a schematic cross-sectional view taken along dash-dot line AA in FIG. 1. In the drawings, semiconductor device 100 includes a semiconductor substrate 1, a copper electrode layer 2, a metallic thin-film layer 3, and a wire 4 which is an interconnection member containing copper. In FIG. 1, the region between the broken lines is a joining region 20 where wire 4 is joined. The region between the dash-dot-dot lines is a joining region 21 between wire 4 and copper electrode layer 2. The region between the broken line and the dash-dot-dot line is a joining region 22 between wire 4 and metallic thin-film layer 3.

With semiconductor substrate 1, a semiconductor element (semiconductor device) is produced. Examples of the types of the semiconductor device include an insulated gate bipolar transistor (IGBT) and a metal oxide semiconductor field effect transistor (MOSFET). Examples of the materials of semiconductor substrate 1 include silicon (Si) and silicon carbide (SiC). The semiconductor device may have any structure, material, and shape that can provide an electrode form in the present embodiment. Specifically, the semiconductor device may have a structure of, for example, a diode. The material of the semiconductor device may be, for example, gallium nitride (GaN).

Copper (Cu) electrode layer 2 is formed on semiconductor substrate 1 (upper face). Copper electrode layer 2 may have any properties (e.g., the density, surface roughness, and electric conductivity). Copper electrode layer 2 may have any shape and area that can ensure a sufficient region for wire bonding. Copper electrode layer 2 is simply required to cover a surface where wire 4 is to be joined. As an electrode structure, a laminated structure may be employed in which aluminium (Al) and copper are laminated in this order from the semiconductor substrate 1 side. Any electrode structure may be applied that allows wire 4 to join to copper electrode layer 2.

Copper electrode layer 2 may have any film thickness, preferably 1 μm or more and 50 μm or less. Copper electrode layer 2 having a film thickness of 1 μm or more is preferable because copper electrode layer 2 having such a thickness can reduce the damage to the primary structure of the electrode at the time of wire bonding, which is another function of copper electrode layer 2. On the other hand, copper electrode layer 3 having a thickness of 50 μm or less is preferable because a too large thickness may disadvantageously cause a stress. The thickness can be selected as appropriate in accordance with the conditions of wire bonding. In the case of a laminated structure with another material, any film thickness may be employed that can alleviate the damage to the primary structure of the electrode. In this case, in particular, copper electrode layer 2 is formed preferably on the surface of semiconductor device 100 after another electrode material is formed on semiconductor substrate 1.

Metallic thin-film layer 3 is formed on copper electrode layer 2 (the upper face of copper electrode layer 2 which is opposite to the face in contact with semiconductor substrate 1). Metallic thin-film layer 3 is not limited to a single layer but may have a laminated structure constituted of two or more layers. Metallic thin-film layer 3 may be composed of any material that has an antioxidant effect for copper electrode layer 2. Examples of the materials of metallic thin-film layer 3 include gold (Au), silver (Ag), palladium (Pd), nickel (Ni), cobalt (Co), chromium (Cr), titanium (Ti), titanium nitride (TiN), and titanium-tungsten alloy (TiW).

Metallic thin-film layer 3 may have any film thickness, preferably 1 nm or more and less than 1000 nm. Metallic thin-film layer 3 has an opening 31. Opening 31 is formed by eliminating a part of metallic thin-film layer 3 in joining region 20 for joining wire 4 when bonding energy is applied for wire bonding. Since opening 31 is formed within joining region 20 where wire 4 is joined, opening 31 is located on the inner side relative to the outer periphery of metallic thin-film layer 3. The wire bonding does not necessarily have to eliminate metallic thin-film layer 3 completely at joining region 21 between copper electrode layer 2 and wire 4. Instead, a part of crushed metallic thin-film layer 3 may insularly remain in joining region 21. In this case, wire 4 will join to copper electrode layer 2 at a plurality of parts in one opening 31. Joining region 21 between copper electrode layer 2 and wire 4 are simply required to be large enough for reliable joining between copper electrode layer 2 and wire 4. For example, joining region 21 between wire 4 and copper electrode layer 2 preferably occupies 20 percent or more of the area of joining region 20 where wire 4 is joined, when seen in plan view. At the joining part where wire 4 and copper electrode layer 2 are joined, they are directly joined.

The purpose of metallic thin-film layer 3 is to prevent the formation of an oxide film on the surface of copper electrode layer 2 to be subjected to wire bonding. Accordingly, metallic thin-film layer 3 is required to have a film thickness that can ensure the antioxidant effect for the surface of copper electrode layer 2. However, too thick metallic thin-film layer 3 cannot be eliminated at the time of wire bonding, thus failing to ensure a region where wire 4 is directly joined to copper electrode layer 2. Thus, the film thickness of metallic thin-film layer 3 should be selected appropriately.

Wire 4 is bonded onto metallic thin-film layer 3. As the material of wire 4, copper (Cu) is used. However, this is not mandatory, but embodiment 1 may employ any material, shape, size, and bonding technique that are applicable to the structure. Instead of wire 4, a ribbon or the like may be used. For example, wire 4 may have a diameter of about 10 μm to 600 μm. Wire 4 may be composed of any material that contains copper as a main component. Wire 4 can be bonded under optimal bonding conditions depending on its shape, size and the like. For example, wire 4 may be a Cu wire having an oxidation resistant coating on its surface.

The bonding energy at the time of bonding eliminates a part of metallic thin-film layer 3. As a result, within joining region 20 where wire 4 is joined, wire 4 includes a region where wire 4 is directly joined to copper electrode layer 2 with no interposition of metallic thin-film layer 3. That is, joining region 20 where wire 4 is joined includes joining region 21 where wire 4 is directly joined to copper electrode layer 2, and joining region 22 where wire 4 is joined to copper electrode layer 2 with interposition of metallic thin-film layer 3. Wire 4 covers opening 31 of metallic thin-film layer 3. At and around opening 31 of metallic thin-film layer 3 in joining region 20, wire 4 is joined to the upper face of metallic thin-film layer 3, the lateral face of metallic thin-film layer 3 (i.e., the inner face of opening 31), and the upper face of copper electrode layer 2.

In order to examine the joining states with and without metallic thin-film layer 3 and the dependence on the thickness of metallic thin-film layer 3, wire bonding experiments were conducted using samples. The samples were obtained by forming metallic thin-film layers 3 having different film thicknesses on respective copper electrode layers 2.

After wire bonding, the cross section form was observed at the wire 4 joining region, and the joining state between wire 4 and copper electrode layer 2 was observed and evaluated. As metallic thin-film layer 3, Ni was used and its film thickness was 50 nm. Wire 4 had a diameter of 400 μm. As the conditions of wire bonding, a copper wire was used and a load of 1 N was applied. The conditions of wire bonding may be selected as appropriate depending on the shape of a bonding jig to be used and the film thickness and material of metallic thin-film layer 3. The load is preferably 1 N or less.

TABLE 1

Metallic thin-film layer

| | Formed | Not formed |
|---|---|---|
| Poor joining | Not occurred | Occurred |

Table 1 shows the results of evaluation of the joining states with and without metallic thin-film layer 3. As the evaluation of the joining state, the cross section form was evaluated. If an interface was found between copper electrode layer 2 and wire 4, poor joining was determined to be “Occurred”; whereas if no interface was found between copper electrode layer 2 and wire 4, poor joining was determine to be “Not occurred”. Table 1 shows that, if metallic thin-film layer 3 is formed on copper electrode layer 2, satisfactory joining between wire 4 and copper electrode layer 2 can be provided. However, if metallic thin-film layer 3 is not formed on copper electrode layer 2, satisfactory interface cannot be provided, with a joining interface existing between copper electrode layer 2 and wire 4. Conceivably this is due to the difference in the surface state of copper electrode layer 2 before the formation of wire 4.

Generally, copper is a material that is very vulnerable to oxidation. Accordingly, if the surface of copper electrode layer 2 is exposed with no metallic thin-film layer 3, the surface of copper electrode layer 2 is oxidized. In this case, when wire 4 is formed, wire 4 is joined to copper electrode layer 2 with interposition of a copper oxide, which makes the direct joining of wire 4 and copper electrode layer 2 difficult.

On the other hand, if metallic thin-film layer 3 is formed on the surface of copper electrode layer 2, a copper oxide is not formed on the surface of copper electrode layer 2 since metallic thin-film layer 3 has an antioxidant effect. At the time of wire bonding, a region of metallic thin-film layer 3 formed on copper electrode layer 2 receives energy from the bonding jig and is thus eliminated in the bonding process. Accordingly, when wire 4 is formed on this region, wire 4 is joined to the surface of copper electrode layer 2 with no interposition of metallic thin-film layer 3 and an oxide. Thus, wire 4 and copper electrode layer 2 are continuous with and directly joined to each other. The surface of copper electrode layer 2 except joining region 21 (opening 31) between copper electrode layer 2 and wire 4 is covered with metallic thin-film layer 3 and is thus not oxidized. Therefore, joining region 21 between copper electrode layer 2 and wire 4 is not subject to any influence (e.g., oxidation) from outside of joining region 21, thus providing and maintaining satisfactory joining. Further, if semiconductor element 1 is sealed with a resin member or the like, the peeling-off of the resin member can be minimized because metallic thin-film layer 3 covering the surface of copper electrode layer 2 blocks its oxidation.

TABLE 2

| | Metallic thin-film layer thickness (nm) | | | | | |
|---|---|---|---|---|---|---|
| | 1 | 10 | 50 | 100 | 500 | 1000 |
| Poor | Not oc- | Not oc- | Not oc- | Not oc- | Oc- | Oc- |
| join- | curred | curred | curred | curred | curred/ | curred |
| ing | | | | | Not oc- | |
| | | | | | curred | |

Table 2 shows the results of evaluation of the joining states between copper wire 4 and copper electrode layer 2 with varied film thicknesses of metallic thin-film layer 3. Wire bonding was performed using evaluation samples having metallic thin-film layers 3 with film thicknesses of 1, 10, 50, 100, 500, and 1000 nm. The method of producing the evaluation samples and the method of evaluation are the same as those for Table 1.

According to Table 2, with metallic thin-film layer 3 having a film thickness of 1 nm to 100 nm, satisfactory joining was provided with no occurrence of poor joining, regardless of the joining conditions. With metallic thin-film layer 3 having a film thickness of 500 nm, there were both cases with and without poor joining, under the same joining conditions as those for the film thicknesses of 100 nm or less. However, with metallic thin-film layer 3 having a film thickness of 1000 nm, poor joining occurred regardless of the joining upper face. Thus, as the upper limit, the film thickness of metallic thin-film layer 3 was set to less than 1000 nm.

As the lower limit, metallic thin-film layer 3 may have any film thickness that can minimize oxidation of copper electrode layer 2. However, too thin metallic thin-film layer 3 may be uneven in thickness with pinholes. Such pinholes may cause the surface of copper electrode layer 2 to be exposed to oxygen through the pinholes, resulting in local oxidation of copper electrode layer 2. This may undermine the antioxidant effect of metallic thin-film layer 3 and may fail to provide satisfactory joining. Therefore, metallic thin-film layer 3 preferably has at least a minimum film thickness that allows metallic thin-film layer 3 to form a uniform film. The minimum film thickness was set to 1 nm.

If metallic thin-film layer 3 is composed of a material that easily reacts with copper (diffuses into copper) (e.g., gold), metallic thin-film layer 3 may diffuse into copper electrode layer 2 during a thermal treatment in the mounting process, from the formation of copper electrode layer 2 to the bonding of wire 4. This may cause metallic thin-film layer 3 to be partially removed from its outermost surface, thus undermining the antioxidant effect for copper electrode layer 2. As a result, the wire bondability of wire 4 to copper electrode layer 2 may be deteriorated. In order to improve the wire bondability of wire 4 to copper electrode layer 2, a material that easily causes counter diffusion with copper should be prevented from diffusing into the copper electrode in the mounting process. For this purpose, metallic thin-film layer 3 may be designed with a laminated structure constituted of an antioxidant film (first metallic thin film) and a diffusion prevention film (second metallic thin film). The diffusion prevention film which prevents diffusion between the antioxidant film and copper may be placed directly on copper electrode layer 2. By doing so, counter diffusion does not occur between the antioxidant film and copper electrode layer 2 during a thermal treatment in the mounting process, thus maintaining the antioxidant effect. The diffusion prevention film which prevents diffusion into copper electrode layer 2 may be composed of any material that does not affect the antioxidant effect of metallic thin-film layer 3. Examples of such materials may include Ti, TiN, TiW, and palladium (Pd). The diffusion prevention film, laminated in metallic thin-film layer 3, may have any thickness that does not exceed (less than) 1000 nm (i.e., the upper limit of the total thickness of the antioxidant film and the diffusion prevention film) and that does not affect the antioxidant effect.

For the purpose of improving the adhesiveness between semiconductor substrate 1 and copper electrode layer 2 and between copper electrode layer 2 and metallic thin-film layer 3, or for the purpose of stabilizing the formation of copper electrode layer 2 on semiconductor substrate 1, intermediate layers may be formed (deposited) between semiconductor substrate 1 and copper electrode layer 2 and between copper electrode layer 2 and metallic thin-film layer 3 to form a laminated structure.

As the material of the intermediate layer between semiconductor substrate 1 and copper electrode layer 2, any material may be selected as appropriate, depending on its purpose, that does not affect the formation of copper electrode layer 2 and metallic thin-film layer 3. If an intermediate layer is formed between semiconductor substrate 1 and copper electrode layer 2 (i.e., on semiconductor substrate 1) for the purpose of improving the adhesiveness between semiconductor substrate 1 and copper electrode layer 2 or stabilizing the formation of copper electrode layer 2, the intermediate may be composed of, for example, titanium (Ti), Al, Ni, Cu, Pd, Ag, Au, or zinc (Zn).

The intermediate layer formed between semiconductor substrate 1 and copper electrode layer 2 may have any film thickness if it does not affect the subsequent formation of copper electrode layer 2.

If an intermediate layer composed of Ti is formed on semiconductor substrate 1 for the purpose of improving the adhesiveness between semiconductor substrate 1 and copper electrode layer 2, the Ti layer may have a film thickness of about 5 nm to 50 nm. In order to function as an adhesive layer, the Ti intermediate layer needs to cover the whole surface of semiconductor substrate 1 as a film. An intermediate layer having a film thickness of 5 nm or less may fail to cover the whole surface of semiconductor substrate 1 as a film, thus possibly resulting in the semiconductor substrate partially having a region with no adhesive layer thereon. While an intermediate layer having a film thickness of 50 nm or more can function as an adhesive layer, the layer does not need to be thicker than is necessary. A too thick intermediate layer may cause an increase in resistive component, thus affecting the properties of the semiconductor device. Accordingly, the upper limit should be set as appropriate according to the type of the semiconductor device. For example, the upper limit of the film thickness may be 50 nm.

If a seed layer composed of Al, Ni, Cu, Pd, Ag, Au, or Zn is formed between semiconductor substrate 1 and copper electrode layer 2 for stabilizing the deposition of copper electrode layer 2, the Al, Ni, Cu, Pd, Ag, Au, or Zn layer may have a film thickness of about 5 nm to 20 μm.

In order to stabilize the deposition of copper electrode layer 2, the seed layer (intermediate layer) needs to cover the whole surface of semiconductor substrate 1 as a film. A seed layer having a film thickness of 5 nm or less may fail to cover the whole surface of semiconductor substrate 1 as a film, thus possibly resulting in copper electrode layer 2 partially having an unstable-deposition region.

In order to stabilize the deposition of copper electrode layer 2 on semiconductor substrate 1, the seed layer is preferably thick enough. While a seed layer having a film thickness of 20 μm or more can stabilize the deposition of copper electrode layer 2, a too thick seed layer may cause an increase in resistive component, thus affecting the properties of the semiconductor device. Also, a too thick seed layer may result in an increased total thickness of the seed layer, copper electrode layer 2, and metallic thin-film layer 3. This results in an increased film stress and an increased stress on semiconductor substrate 1, thus possibly deteriorating the properties of the semiconductor device. The upper limit should be set as appropriate according to the type and film thickness of the seed layer and copper electrode layer 2. For example, the upper limit of the film thickness of the seed layer may be 20 μm.

If an intermediate layer is formed between copper electrode layer 2 and metallic thin-film layer 3 (i.e., on copper electrode layer 2) for the purpose of improving the adhesiveness between copper electrode layer 2 and metallic thin-film layer 3 or stabilizing the formation of metallic thin-film layer 3, the intermediate layer may be composed of, for example, Ti, Pd, Ag, Au, or Zn.

The intermediate layer deposited between copper electrode layer 2 and metallic thin-film layer 3 may have any film thickness if it does not affect the formation of metallic thin-film layer 3.

If an intermediate layer (seed layer) composed of Ti, Pd, Ag, Au, or Zn is formed on copper electrode layer 2 for the purpose of improving the adhesiveness between copper electrode layer 2 and metallic thin-film layer 3 and stabilizing the deposition of metallic thin-film layer 3, the Ti, Pd, Ag, Au, or Zn layer may have a film thickness of about 5 nm to 100 nm. In order to improve the adhesiveness and stabilize the film deposition, the intermediate layer needs to cover the whole surface of copper electrode layer 2 as a film. An intermediate layer having a film thickness of 5 nm or less may fail to cover the whole surface of copper electrode layer 2 as a film, thus possibly resulting in copper electrode layer 2 partially having a region with no intermediate layer thereon. While an intermediate layer having a film thickness of 100 nm or more can function as an intermediate layer, the layer does not need to be thicker than is necessary. A too thick intermediate layer may cause an increase in resistive component, thus affecting the properties of the semiconductor device. Accordingly, the upper limit should be set as appropriate according to the type of the semiconductor device. For example, the film thickness of the intermediate layer may be 100 nm.

Any number of intermediate layers may be deposited between semiconductor substrate 1 and copper electrode layer 2 and between copper electrode layer 2 and metallic thin-film layer 3 if the intermediate layers do not affect the formation of copper electrode layer 2 and metallic thin-film layer 3.

Next, a method for manufacturing semiconductor device 100 is described.

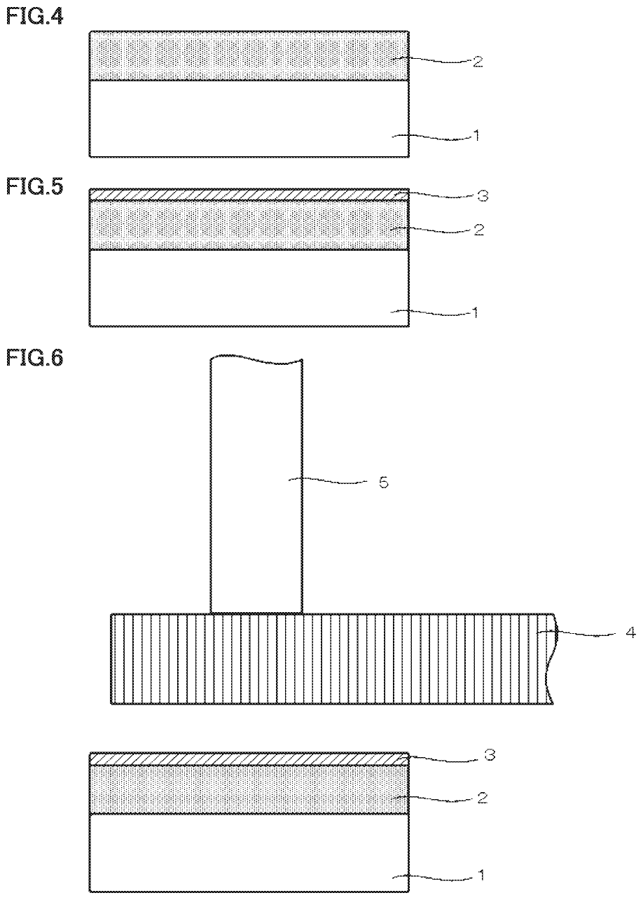

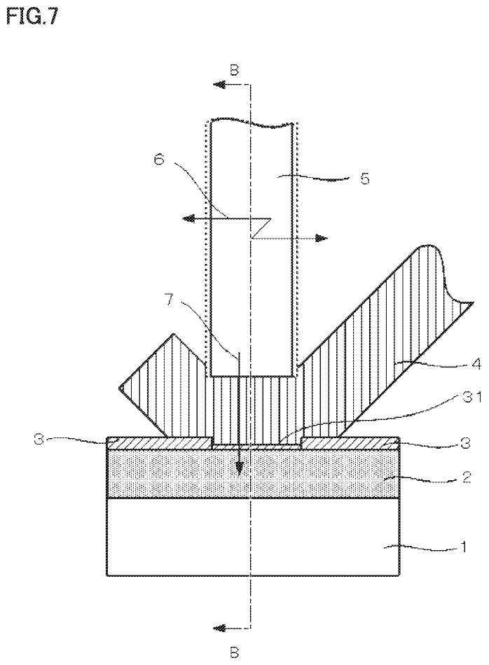

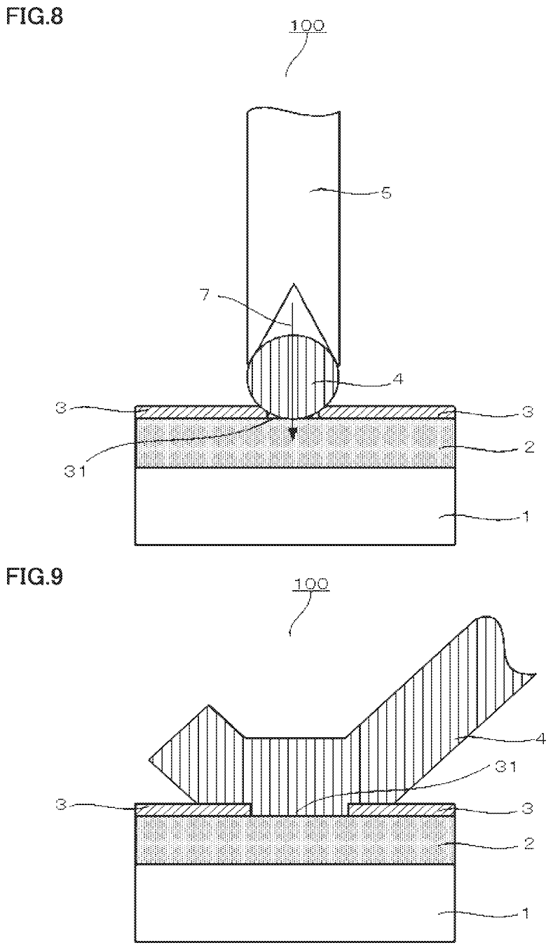

FIG. 3 to FIG. 9 are schematic cross-sectional views showing the steps for manufacturing a semiconductor device in embodiment 1 of the present invention. FIG. 3 is a schematic cross-sectional view showing a step for manufacturing a semiconductor device in embodiment 1 of the present invention. FIG. 4 is a schematic cross-sectional view showing a step for manufacturing a semiconductor device in embodiment 1 of the present invention. FIG. 5 is a schematic cross-sectional view showing a step for manufacturing a semiconductor device in embodiment 1 of the present invention. FIG. 6 is a schematic cross-sectional view showing a step for manufacturing a semiconductor device in embodiment 1 of the present invention. FIG. 7 is a schematic cross-sectional view showing a step for manufacturing a semiconductor device in embodiment 1 of the present invention. FIG. 8 is a schematic cross-sectional view showing a step for manufacturing a semiconductor device in embodiment 1 of the present invention. FIG. 9 is a schematic cross-sectional view showing a step for manufacturing a semiconductor device in embodiment 1 of the present invention. Through the manufacturing steps from FIG. 3 to FIG. 9, semiconductor device 100 can be produced.

First, as shown in FIG. 3, semiconductor substrate 1 is prepared (semiconductor substrate preparation step). Semiconductor substrate 1 has already been subjected to a treatment necessary for the semiconductor device. Examples of such treatments may include introducing an impurity into semiconductor substrate 1 for an intended conductivity type, and etching for prescribed shaping.

Next, as shown in FIG. 4, copper electrode layer 2 is formed on semiconductor substrate 1 (front face) on which a prescribed treatment has been performed (copper electrode layer formation step). Examples of the methods for forming copper electrode layer 2 may include electrochemical deposition (ECD), chemical vapor deposition (CVD), physical vapor deposition (PVD), and application of a copper paste.

The ECD may be, for example, plating. There are two types of plating, electroless plating and electrolytic plating, but any formation method may be used if it does not affect the formation of copper electrode layer 2. As to the detailed processes in the plating, any step, technique, and formation conditions may be employed if intended copper electrode layer 2 can be formed.

The CVD may be, for example, plasma CVD. Examples of the types of CVD include thermal CVD, photo-CVD, and atomic-layer CVD, but any formation method may be used if it does not affect the formation of copper electrode layer 2.

The PVD may be, for example, sputter deposition. There are many types of sputter deposition, such as magnetron sputtering, vapor deposition, and ion-beam sputtering, but any sputtering method may be used if intended copper electrode layer 2 can be formed. Examples of the types of power sources for sputtering include a DC power source and an AC power source, but any sputtering method may be used if intended copper electrode layer 2 can be formed.

As a copper paste, any material composition may be applied if it contains copper as a main component and can be formed into an electrode. Examples of the methods for applying a copper paste may include dispensing and printing, but any method may be used if it does not affect the subsequent wire bonding and formation of metallic thin-film layer 3.

The deposition conditions include many setting parameters, such as the presence or absence of heat, the presence or absence of an assisting agent for deposition, and the numerical values of the applied power and flow rate. Any deposition conditions may be employed if intended copper electrode layer 2 can be formed.

If plating is performed for deposition, a primary layer and, as needed, an adhesive layer should be formed on semiconductor substrate 1 for plating deposition, whether it is electroless plating or electrolytic plating.

As a method for forming the primary layer and the adhesive layer, the above-described ECD, CVD, or PVD may be used. As a method for forming the primary layer and the adhesive layer, any method may be used if an intended film can be formed without affecting the formation of the plating film. From the viewpoint of the device configuration and the required film thickness for forming the seed layer and the adhesive layer, sputter deposition is preferably used for forming the primary layer and the adhesive layer.

Next, as shown in FIG. 5, metallic thin-film layer 3 is formed on copper electrode layer 2 (front face) (metallic thin-film layer formation step). As a method for forming metallic thin-film layer 3, ECD, CVD, or PVD listed above as a method for forming copper electrode layer 2 may be used. As a method for forming metallic thin-film layer 3, any method may be used if an intended film can be formed without affecting the subsequent bonding of wire 4.

In order to prevent the formation of an oxide film on the front face of copper electrode layer 2, it is preferable that the metallic thin-film layer formation step immediately follows the copper electrode layer formation step. If the ECD is used for forming copper electrode layer 2, the ECD is preferably used for forming metallic thin-film layer 3. If the CVD is used for forming copper electrode layer 2, the CVD is preferably used for forming metallic thin-film layer 3. If the PVD is used for forming copper electrode layer 2, the PVD is preferably used for forming metallic thin-film layer 3.

Before the metallic thin film formation step, the oxide film formed on copper electrode layer 2 may be removed in the following cases: the case in which different formation methods are used between the copper electrode layer formation step and the metallic thin-film layer formation step; and the case in which, although the same deposition method is used for the copper electrode layer formation step and the metallic thin-film layer formation step, the deposited copper electrode layer 2 is placed in an environment involving a risk of oxidation, such as an environment in which copper electrode layer 2 is exposed to the air or placed in the water for a long time.

Examples of the treatments for removing the oxide film formed on copper electrode layer 2 include dry etching and wet etching, but any etching method may be used if it can remove an intended oxide film. Examples of wet etching include applying a remover to remove the oxide film formed on copper electrode layer 2, and etching the outermost surface of copper electrode layer 2 for liftoff of the oxide film. Examples of dry etching include a plasma treatment for eliminating the surface. Examples of the gases to be used include an argon (Ar) gas.

Next, as shown in FIG. 6, FIG. 7, and FIG. 8, a wire is bonded to metallic thin-film layer 3 formed on copper electrode layer 2 (interconnection member joining step). As a method for bonding wire 4, any method may be used that can achieve intended joining. In this case, for joining wire 4 to metallic thin-film layer 3, the application of energy is required for eliminating a part of metallic thin-film layer 3. In order to obtain an intended joint form, wire bonding with pressure and ultrasonic waves is preferable. There are various methods of such wire bonding with pressure and ultrasonic waves, one of which is ball bonding in which a wire end is melted by heat into a ball for joining. An appropriate method may be selected in accordance with the diameter and material of the wire, and its purpose.

The present embodiment describes a method of wire bonding with pressure and ultrasonic waves. FIG. 8 is a schematic cross-sectional view taken along dash-dot line BB in FIG. 7. In FIG. 6, FIG. 7, and FIG. 8, a bonding jig 5 with wire 4 attached thereto is placed on the top of semiconductor substrate 1 on which copper electrode layer 2 and metallic thin-film layer 3 have been formed thereon. After jig 5 is placed, jig 5 is pressed against metallic thin-film layer 3 through wire 4 so as to bond wire 4 to metallic thin-film layer 3 and copper electrode layer 2 with pressure. The loading direction of jig 5 is indicated by an arrow 7. In order to press wire 4 against metallic thin-film layer 3, a prescribed pressure is applied to jig 5 in the direction of arrow 7, from the top of wire 4 toward semiconductor substrate 1. If the pressure applied in the direction of arrow 7 is weak, it may fail to eliminate metallic thin-film layer 3 and fail to achieve satisfactory joining. On the other hand, if the pressure is strong, it may break not only metallic thin-film layer 3 but also copper electrode layer 2 and damage the device. Accordingly, conditions appropriate for bonding should be selected. For example, 0.1 N to 1 N may be applied. At this time, simultaneously with the application of the pressure, ultrasonic waves having a prescribed frequency are applied to jig 5. The direction of the application of ultrasonic waves to jig 5 is indicated by a double-pointed arrow 6. Ultrasonic waves are applied to jig 5 in the direction orthogonal to loading direction 7 of jig 5. The frequency of the ultrasonic waves may be, for example, 0 to 500 Hz. In FIG. 7, the region indicated by the dotted lines around jig 5 is an image of oscillation caused by the application of ultrasonic waves to jig 5. By applying pressure and ultrasonic waves in this way, wire 4 is joined to the region under jig 5 (joining region 20 in FIG. 1).

By applying ultrasonic waves to jig 5 simultaneously with pressure, a region of metallic thin-film layer 3 that has received ultrasonic energy from jig 5 is eliminated from copper electrode layer 2. Thus, a new surface of copper electrode layer 2 is exposed. This new surface corresponds to opening 31 in FIG. 2 at which wire 4 is joined to copper electrode layer 2. In this way, satisfactory joining can be provided between copper electrode layer 2 and wire 4 with no interface (e.g., oxide film) therebetween.

Through these steps, semiconductor device 100 as shown in FIG. 9 can be produced.

In the semiconductor device configured as described above, wire 4 is joined to copper electrode layer 2 and metallic thin-film layer 3 at the joining region. Thus, satisfactory joining is provided between wire 4 and copper electrode layer 2.

The satisfactory joining results in improvement in the reliability of semiconductor device 100.

### Embodiment 2

Embodiment 2 is different from embodiment 1 in the shapes of copper electrode layer 2 and metallic thin-film layer 3. Specifically, in embodiment 2, copper electrode layer 2 and metallic thin-film layer 3 are not uniform in film thickness, but metallic thin-film layer 3 is reduced in film thickness at the part where wire 4 is joined to copper electrode layer 2. Since metallic thin-film layer 3 is reduced in film thickness at the part joined to wire 4, metallic thin-film layer 3 can be easily eliminated when wire 4 is joined to copper electrode layer 2, thus easily providing satisfactory joining. In the other respects, embodiment 2 is the same as embodiment 1, and the detailed description is not repeated.

First, a configuration of a semiconductor device 200 in embodiment 2 of the present invention is described.

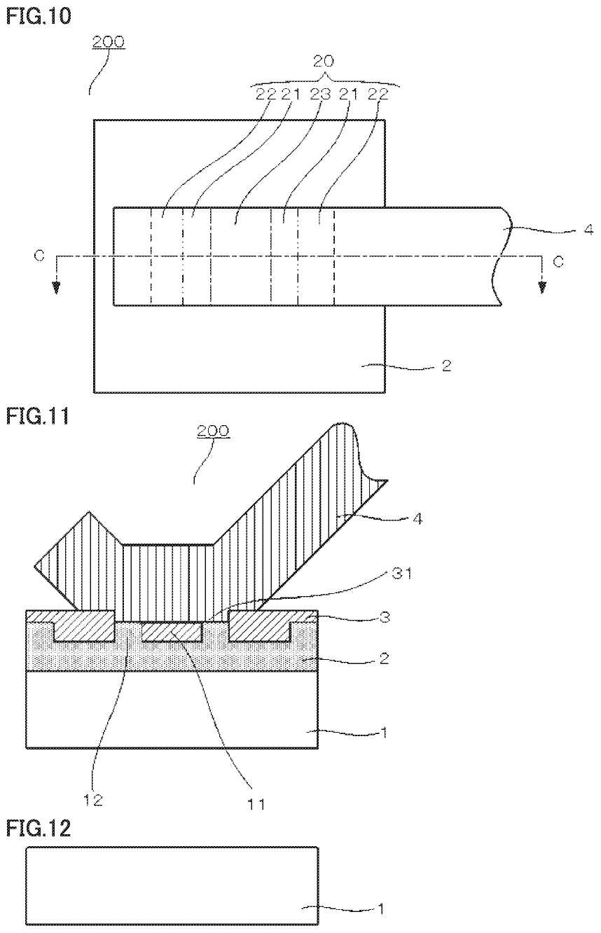

FIG. 10 is a schematic plan view showing a semiconductor device in embodiment 2 of the present invention. FIG. 11 is a schematic cross-sectional view showing a semiconductor device in embodiment 2 of the present invention. FIG. 11 is a schematic cross-sectional view taken along dash-dot line CC in FIG. 10. In the drawings, semiconductor device 200 includes semiconductor substrate 1, copper electrode layer 2, metallic thin-film layer 3, and wire 4 which is an interconnection member containing copper. In FIG. 10, the region between the broken lines is joining region 20 where wire 4 is joined. The region between the dash-dot-dot line and the dash-dot line is joining region 21 between wire 4 and copper electrode layer 3. The region between the broken line and the dash-dot-dot line is joining region 22 between wire 4 and metallic thin-film layer 3. The region between the dash-dot lines is a joining region 23 between wire 4 and metallic thin-film layer 3. Further, in FIG. 11, copper electrode layer 2 has projections and recesses (a recess 11 and a projection 12) on its upper face. Metallic thin-film layer 3 has projections and recesses corresponding to (reversed in shape to) the projections and recesses of copper electrode layer 2.

Copper electrode layer 2 has projections and recesses (recess 11 and projection 12) on its upper face (surface). By forming recess 11 and projection 12 on copper electrode layer 2, copper electrode layer 2 has regions with different thicknesses. By forming recess 11 and projection 12 on copper electrode layer 2, the film thickness of metallic thin-film layer 3 formed on copper electrode layer 2 varies according to recess 11 and projection 12 formed on copper electrode layer 2. If metallic thin-film layer 3 is thin relative to recess 11 and projection 12, metallic thin-film layer 3 may not fully fill recess 11. If metallic thin-film layer 3 is thin relative to recess 11 and projection 12, metallic thin-film layer 3 may be formed on recess 11 and projection 12 with a uniform film thickness.

Specifically, at recess 11 of copper electrode layer 2, metallic thin-film layer 3 is thicker and is not easily eliminated at the time of wire bonding. However, at projection 12 of copper electrode layer 2, metallic thin-film layer 3 is thinner and is easily eliminated at the time of wire bonding, thus allowing wire 4 to be easily joined to copper electrode layer 2.

Recesses 11 and projections 12 may be formed on copper electrode layer 2 at any interval. If the region where wire 4 is joined to copper electrode layer 2 is increased, satisfactory joining can be more easily provided. However, if the region where wire 4 is joined is too small, the resistance will increase when the semiconductor device operates. Therefore, the region should be large enough not to affect the properties of the semiconductor device. After wire 4 is joined, the proportion of the area of recess 11 and projection 12 of copper electrode layer 2 to the area of opening 31, when seen in plan view, may be set to any proportion if the joining region between copper electrode layer 2 and wire 4 occupies 20 percent or more of the area of opening 31. In order to ensure such a joining region, projection 12 of copper electrode layer 2 preferably occupies 20 percent or more of the area of opening 31. In this case, wire 4 is joined to a plurality of projections 12 of copper electrode layer 2. That is, wire 4 is joined to copper electrode layer 2 at a plurality of parts.

Next, a method for manufacturing a semiconductor device in embodiment 2 is described.

The manufacturing method in embodiment 2 is different from the manufacturing method in embodiment 1 in that the manufacturing method in embodiment 2 additionally includes a step of forming projections and recesses (recess 11 and projection 12) on copper electrode layer 2.

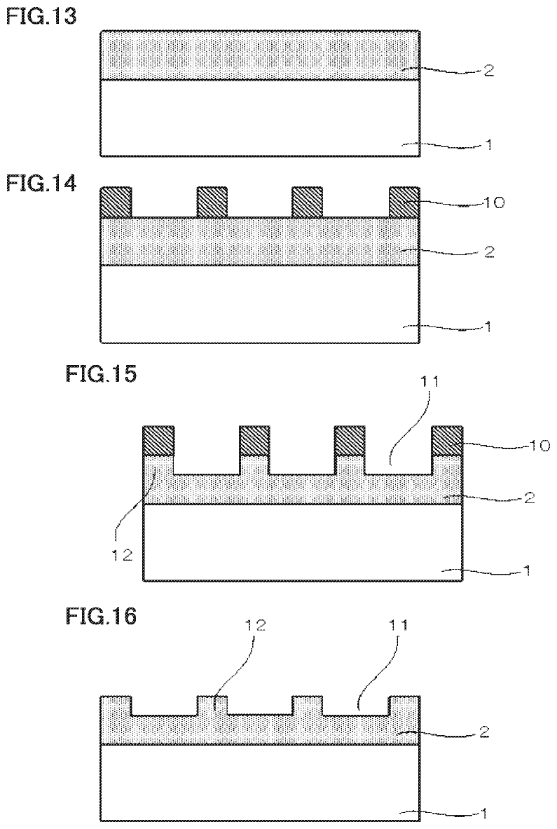

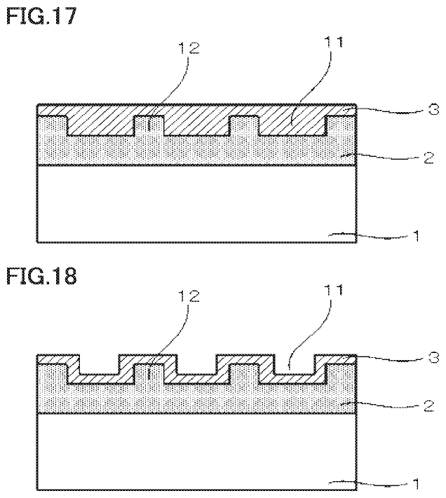

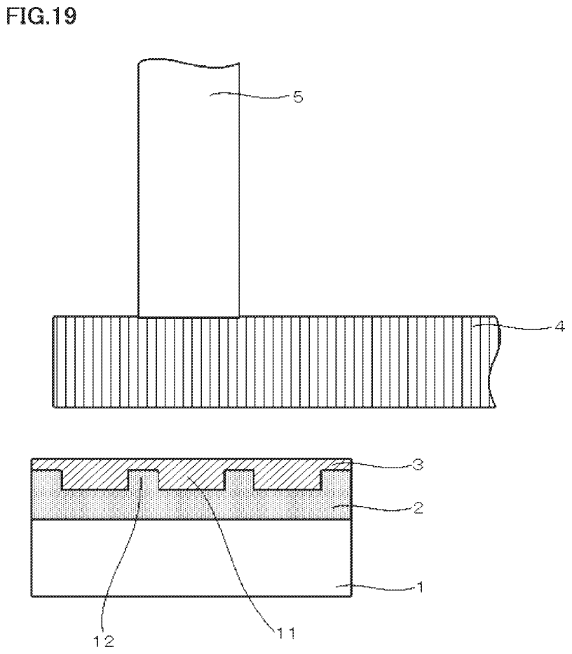

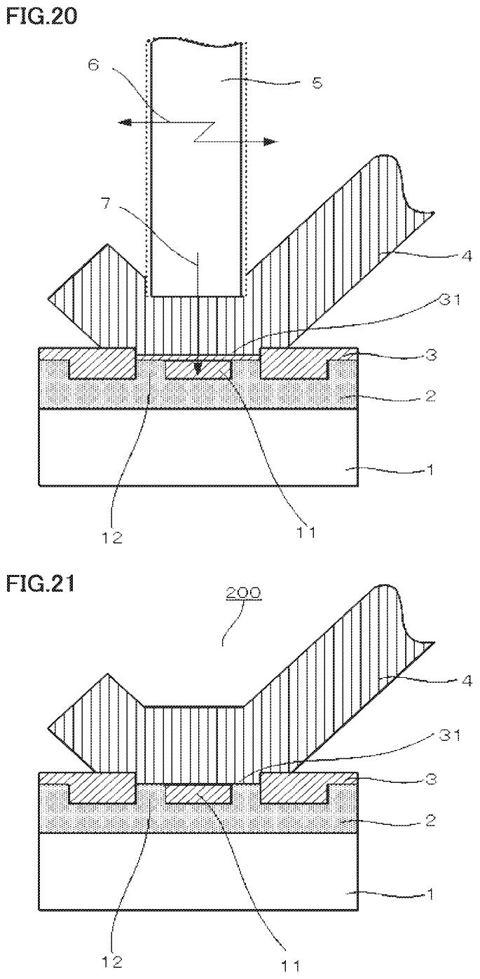

FIG. 12 to FIG. 21 are schematic cross-sectional views showing the steps for manufacturing a semiconductor device in embodiment 2 of the present invention. FIG. 12 is a schematic cross-sectional view showing a step for manufacturing a semiconductor device in embodiment 2 of the present invention. FIG. 13 is a schematic cross-sectional view showing a step for manufacturing a semiconductor device in embodiment 2 of the present invention. FIG. 14 is a schematic cross-sectional view showing a step for manufacturing a semiconductor device in embodiment 2 of the present invention. FIG. 15 is a schematic cross-sectional view showing a step for manufacturing a semiconductor device in embodiment 2 of the present invention. FIG. 16 is a schematic cross-sectional view showing a step for manufacturing a semiconductor device in embodiment 2 of the present invention. FIG. 17 is a schematic cross-sectional view showing a step for manufacturing a semiconductor device in embodiment 2 of the present invention. FIG. 18 is a schematic cross-sectional view showing a step for manufacturing a semiconductor device in embodiment 2 of the present invention. FIG. 19 is a schematic cross-sectional view showing a step for manufacturing a semiconductor device in embodiment 2 of the present invention. FIG. 20 is a schematic cross-sectional view showing a step for manufacturing a semiconductor device in embodiment 2 of the present invention. FIG. 21 is a schematic cross-sectional view showing a step for manufacturing a semiconductor device in embodiment 2 of the present invention. Through the manufacturing steps from FIG. 12 to FIG. 21, semiconductor device 200 can be produced. If the shape shown in FIG. 18 is employed, the shape is applied to the steps after the step of FIG. 18.

First, as shown in FIG. 12, semiconductor substrate 1 is prepared (semiconductor substrate preparation step). Semiconductor substrate 1 has already been subjected to a treatment necessary for the semiconductor device. Examples of such treatments may include introducing an impurity into semiconductor substrate 1 for an intended conductivity type, and etching for shaping.

Next, as shown in FIG. 13, copper electrode layer 2 is formed on the front face of semiconductor substrate 1 on which a prescribed treatment has been performed (copper electrode layer formation step). Examples of the methods for forming copper electrode layer 2 may include electrochemical deposition (ECD), chemical vapor deposition (CVD), and physical vapor deposition (PVD). Application of a copper paste may also be used.

The ECD may be, for example, plating. There are two types of plating, electroless plating and electrolytic plating, but any formation method may be used if it does not affect the formation of copper electrode layer 2. As to the detailed processes in the plating, any step, technique, and formation conditions may be employed if intended copper electrode layer 2 can be formed.

The CVD may be, for example, plasma CVD. Examples of the types of CVD include thermal CVD, photo-CVD, and atomic-layer CVD, but any formation method may be used if it does not affect the formation of copper electrode layer 2.

The PVD may be, for example, sputter deposition. There are many types of sputter deposition, such as magnetron sputtering, vapor deposition, and ion-beam sputtering, but any sputtering method may be used if intended copper electrode layer 2 can be formed. Examples of the types of power sources for sputtering include a DC power source and an AC power source, but any sputtering method may be used if intended copper electrode layer 2 can be formed.

For the application of a copper paste, any material that can serve as an electrode may be used. Examples of the application methods may include dispensing and printing, but any method may be used if it does not affect the wire bonding and the formation of the metallic thin film.

The deposition conditions include many setting parameters, such as the presence or absence of heat, the presence or absence of an assisting agent for deposition, and the numerical values of the applied power and flow rate. Any deposition conditions may be employed if intended copper electrode layer 2 can be formed.

If plating is performed for deposition, a primary layer and, as needed, an adhesive layer should be formed on semiconductor substrate 1 for plating deposition, whether it is electroless plating or electrolytic plating.

As a method for forming the primary layer and the adhesive layer, the above-described ECD, CVD, or PVD may be used. As a method for forming the primary layer and the adhesive layer, any method may be used if an intended film can be formed without affecting the formation of the plating film. From the viewpoint of the device configuration and the required film thickness for forming the seed layer and the adhesive layer, sputter deposition is preferably used for forming the primary layer and the adhesive layer.

Next, as shown in FIG. 14, a mask member 10 for processing copper electrode layer 2 is formed (processing mask formation step). A patterned mask member 10 formed in this step may be any mask member 10 if it allows copper electrode layer 2 to be processed into an intended shape as a result of the subsequent processing (etching).

Specifically, examples of the masks include a metal mask prepared separately from semiconductor substrate 1 and a resist mask directly formed on copper electrode layer 2. If a metal mask is used to process copper electrode layer 2, any metal may be used if copper electrode layer 2 can be processed into an intended shape. Also, a material other than a metal may be used if copper electrode layer 2 can be processed into an intended shape.

If a photoresist is used as mask member 10, examples of the resist type include a positive resist and a negative resist. Any type of resist may be used if it does not affect the shape of processed copper electrode layer 2.

The following describes the formation of a photoresist pattern on copper electrode layer 2 using a photoresist. A photoresist is applied onto copper electrode layer 2. The applied photoresist is then spread over the whole surface of copper electrode layer 2 uniformly by a spin coater. On semiconductor substrate 1 with the uniformly spread wet resist, a photomask is placed. Then, semiconductor substrate 1 is irradiated with ultraviolet rays from an exposure machine. After irradiated with ultraviolet rays, semiconductor substrate 1 with the resist is immersed in a developing solution, and the uncured resist is removed. The photomask used herein has a shape such that the formed resist pattern will be the same size as the electrode.

The material of mask member 10 is not limited to a resist, but may be any material that enables processing into an intended shape. The method of application and the method of removing the unnecessary portions may be selected as appropriate in accordance with the properties of mask member 10.

Next, as shown in FIG. 15, copper electrode layer 2 is processed using mask member 10 produced in the processing mask formation step (copper electrode layer processing step). The portion where copper electrode layer 2 has been removed by etching constitutes recess 11, and both sides of recess 11 constitute projections 12. Any method may be used for etching copper electrode layer 2 if intended etching can be carried out, such as dry etching and wet etching. Examples of the etching include isotropic etching and anisotropic etching. Any etching method may be used if it can provide an intended shape. However, in order to produce a structure that is closer to an intended shape, anisotropic dry etching is preferably used.

If wet etching is applied to copper electrode layer 2, any type of chemical agent may be used for the wet etching if it can process copper electrode layer 2 into an intended shape. If dry etching is applied to copper electrode layer 2, any technique (any principle and device type) may be used for the dry etching if it can process copper electrode layer 2 into an intended shape.

Next, as shown in FIG. 16, mask member 10 is removed (processing mask member removal step). If mask member 10 used in the processing mask formation step was a mask independent of the sample (e.g., metal mask), it may be just removed. If mask member 10 was a mask directly adhering to copper electrode layer 2 (e.g., a resist), it may be removed by, for example, wet etching or dry etching. In order to remove mask member 10 (e.g., a resist) while maintaining the shapes of recess 11 and projection 12 of copper electrode layer 2 that were formed in the previous copper electrode layer processing step, wet etching is preferably used to selectively remove only the mask member (e.g., a resist). Any etching solution may be used for the wet etching that can remove the mask member (e.g., a resist) while maintaining copper electrode layer 2 in an intended shape.

Next, as shown in FIG. 17, metallic thin-film layer 3 is formed on copper electrode layer 2 (metallic thin-film layer formation step). As a method for forming metallic thin-film layer 3, CVD or PVD listed above as a method for forming copper electrode layer 2 may be used. As a method for forming metallic thin-film layer 3, any method may be used if an intended film can be formed without affecting the subsequent bonding of wire 4.

In the present embodiment, since copper electrode layer 2 is processed after being formed, the formation of metallic thin-film layer 3 cannot immediately follow the formation of copper electrode layer 2. Accordingly, before the metallic thin film formation step, the oxide film formed on copper electrode layer 2 should be removed, as in the case in which the deposited copper electrode layer 2 is placed in an environment involving a risk of oxidation, such as an environment in which copper electrode layer 2 is exposed to the air or placed in the water for a long time.

Examples of the treatments for removing the oxide film formed on copper electrode layer 2 include dry etching and wet etching, but any etching method may be used if it can remove an intended oxide film. Examples of wet etching include applying a remover to remove the oxide film formed on copper electrode layer 2, and etching the outermost surface of copper electrode layer 2 for liftoff of the oxide film. Examples of dry etching include a plasma treatment for eliminating (etching) the surface. Examples of the gases to be used include an argon (Ar) gas.

In order to vary the thickness of metallic thin-film layer 3 effectively in accordance with the shape of copper electrode layer 2, metallic thin-film layer 3 is preferably formed by plating rather than sputtering because plating provides better embeddability than sputtering which involves an etching component. After metallic thin-film layer 3 is formed, metallic thin-film layer 3 may be subjected to a treatment for flattening and improving the embeddability of metallic thin-film layer 3 into recess 11 on copper electrode layer 2. Examples of such treatments may include a thermal treatment. As a method for forming metallic thin-film layer 3, any method may be used if it can ensure good bondability of wire 4. If a thermal treatment is performed, any temperature, time, and atmosphere may be employed. If metallic thin-film layer 3 is thin relative to recess 11 and projection 12 as shown in FIG. 18, metallic thin-film layer 3 may be formed with a uniform film thickness on recess 11 and projection 12, rather than filling recess 11.

Next, as shown in FIG. 19 and FIG. 20, a wire is bonded to metallic thin-film layer 3 formed on copper electrode layer 2 (interconnection member joining step). As a method for bonding wire 4, any method may be used that can achieve intended joining. In this case, for joining wire 4 to metallic thin-film layer 3, the application of energy is required for eliminating a part of metallic thin-film layer 3. In order to obtain an intended joint form, wire bonding with pressure and ultrasonic waves is preferable. There are various methods of such wire bonding with pressure and ultrasonic waves, one of which is ball bonding in which a wire end is melted by heat into a ball for joining. An appropriate method may be selected in accordance with the diameter and material of the wire, and its purpose.

The present embodiment describes a method of wire bonding with pressure and ultrasonic waves. In FIG. 19 and FIG. 20, bonding jig 5 with wire 4 attached thereto is placed on the top of semiconductor substrate 1 on which copper electrode layer 2 and metallic thin-film layer 3 have been formed thereon. After jig 5 is placed, jig 5 is pressed against metallic thin-film layer 3 through wire 4 so as to bond wire 4 to metallic thin-film layer 3 and copper electrode layer 2 with pressure. The loading direction of jig 5 is indicated by arrow 7. In order to press wire 4 against metallic thin-film layer 3, a prescribed pressure is applied to jig 5 in the direction of arrow 7, from the top of wire 4 toward semiconductor substrate 1. If the pressure applied in the direction of arrow 7 is weak, it may fail to eliminate metallic thin-film layer 3 and fail to achieve satisfactory joining. On the other hand, if the pressure is strong, it may break not only metallic thin-film layer 3 but also copper electrode layer 2 and damage the device. Accordingly, conditions appropriate for bonding should be selected. For example, 0.1 N to 1 N may be applied. At this time, simultaneously with the application of the pressure, ultrasonic waves having a prescribed frequency are applied to jig 5. The direction of the application of ultrasonic waves to jig 5 is indicated by double-pointed arrow 6. Ultrasonic waves are applied to jig 5 in the direction orthogonal to loading direction 7 of jig 5. The frequency of the ultrasonic waves may be, for example, 0 to 500 Hz. In FIG. 20, the region indicated by the dotted lines around jig 5 is an image of oscillation caused by the application of ultrasonic waves to jig 5. By applying pressure and ultrasonic waves in this way, wire 4 is joined to the region under jig 5 (joining region 20 in FIG. 1).

By applying ultrasonic waves to jig 5 simultaneously with pressure, a region of metallic thin-film layer 3 that has received ultrasonic energy from jig 5 is eliminated from copper electrode layer 2. Thus, a new surface of copper electrode layer 2 is exposed. This new surface corresponds to opening 31 in FIG. 10 at which wire 4 is joined to copper electrode layer 2. In this way, satisfactory joining can be provided between copper electrode layer 2 and wire 4 with no interface (e.g., oxide film) therebetween.

Through these steps, semiconductor device 200 as shown in FIG. 21 can be produced.

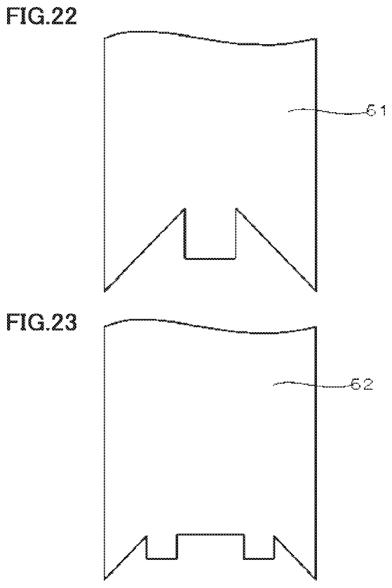

FIG. 22 is a schematic cross-sectional view of another jig to be used for a step for manufacturing a semiconductor device in embodiment 2 of the present invention. FIG. 23 is a schematic cross-sectional view of another jig to be used for a step for manufacturing a semiconductor device in embodiment 2 of the present invention.

As a jig for use in the interconnection member joining step, jig 5 as shown in FIG. 19 etc. may be used. However, in order to shape metallic thin-film layer 3 (copper electrode layer 2) more effectively, jigs 51, 52 having the shapes as shown in FIG. 22 and FIG. 23 may be used for wire bonding. In this case, metallic thin-film layer 3 can be removed effectively in accordance with the shape of copper electrode layer 2 (metallic thin-film layer 3), thus providing satisfactory joining between copper electrode layer 3 and wire 4. Further, jigs 51, 52, which come in contact with wire 4 through multiple points, can uniformly apply pressure to wire 4 with light load and can thus provide satisfactory joining.

In the semiconductor device configured as described above, wire 4 is joined to copper electrode layer 2 and metallic thin-film layer 3 at the joining region. Thus, satisfactory joining is provided between wire 4 and copper electrode layer 2.

The satisfactory joining results in improvement in the reliability of semiconductor device 200.

Further, since projections and recesses are formed on copper electrode layer 2 and metallic thin-film layer 3 for wire bonding, the region where wire 4 is to be joined to copper electrode layer 2 can be set as desired. Thus, satisfactory joining can be easily provided.

### REFERENCE SIGNS LIST

1: semiconductor substrate; 2: copper electrode layer; 3: metallic thin-film layer; 4: wire; 5, 51, 52: jig; 6: direction of application of ultrasonic waves to jig; 7: loading direction of jig; 10: mask member; 11: recess; 12: projection; 20: wire joining region; 21: joining region between wire and copper electrode layer; 22, 23: joining region between wire and metallic thin-film layer; 31: opening; 100, 200: semiconductor device

1: A semiconductor device comprising:
a semiconductor substrate;
a copper electrode layer formed on the semiconductor substrate;
a metallic thin-film layer formed on the copper electrode layer for preventing oxidation of the copper electrode layer, the metallic thin-film layer having an opening through which the copper electrode layer is exposed, the opening being located on an inner side relative to an outer periphery of the metallic thin-film layer; and
an interconnection member containing copper as a main component, the interconnection member including a joining region covering the opening, the interconnection member being joined to the metallic thin-film layer and joined to a plurality of parts of the copper electrode layer in the opening.

2: The semiconductor device according to claim 1, wherein the metallic thin-film layer has a laminated structure comprising two or more layers.

3: The semiconductor device according to claim 1, wherein the interconnection member is joined to the copper electrode layer at a plurality of parts in the opening at the joining region.

4: The semiconductor device according to claim 1, wherein the metallic thin-film layer includes regions having different film thicknesses at the joining region.

5: The semiconductor device according to claim 1, wherein the metallic thin-film layer has a total thickness of 1 nm or more and less than 1000 nm.

6: The semiconductor device according to claim 1, wherein the metallic thin-film layer includes any of gold, silver, palladium, nickel, cobalt, chromium, aluminium, titanium, titanium nitride, and titanium-tungsten alloy.

7: The semiconductor device according to claim 1, wherein the copper electrode layer is a film formed by any of electroless plating, electrolytic plating, sputtering, and sintering.

8: A method for manufacturing a semiconductor device, the method comprising:
a semiconductor substrate preparation step of preparing a semiconductor substrate;
a copper electrode layer formation step of forming a copper electrode layer on the semiconductor substrate;
a metallic thin-film layer formation step of forming a metallic thin-film layer on the copper electrode layer; and
an interconnection member joining step of forming an opening at a joining region of the metallic thin-film layer, and joining an interconnection member to the metallic thin-film layer and to the copper electrode layer exposed through the opening, the interconnection member containing copper as a main component, an outer periphery of the joining region being located on the metallic thin-film layer.

9: The method for manufacturing a semiconductor device according to claim 8, further comprising a copper electrode layer processing step of forming a projection and a recess on a front face of the copper electrode layer.

10: A semiconductor device comprising:
a semiconductor substrate;
a copper electrode layer formed on the semiconductor substrate;
a metallic thin-film layer formed on the copper electrode layer for preventing oxidation of the copper electrode layer, the metallic thin-film layer having an opening through which the copper electrode layer is exposed, the opening being located on an inner side relative to an outer periphery of the metallic thin-film layer; and
an interconnection member containing copper as a main component, the interconnection member including a joining region covering the opening, the interconnection member being joined to the metallic thin-film layer and joined to the copper electrode layer in the opening, an outer periphery of the joining region being located on the metallic thin-film layer.

11: The semiconductor device according to claim 10, wherein, when seen in plan view, at least a short side of the outer periphery of the joining region of the interconnection member is located on the metallic thin-film layer.
